(19) United States
(12) Patent Application Publication
(10) Pub. No.: US 2026/0176737 A1
(43) Pub. Date: Jun. 25, 2026

(54) MASK ASSEMBLY, EVAPORATION METHOD, AND EVAPORATION DEVICE

(71) Applicant: JI HUA LABORATORY, Foshan (CN)

(72) Inventor: Yixin YANG, Foshan (CN)

(21) Appl. No.: 19/125,722

(22) PCT Filed: Aug. 1, 2023
(86) PCT No.: PCT/CN2023/110462

§ 371 Date: Apr. 29, 2025

(30) Foreign Application Priority Data
Nov. 9, 2022 (CN) 202211397946.7

(51) Int. Cl. C23C 14/04; C23C 14/24; C23C 14/54; H10K 71/16

(52) U.S. Cl. CPC C23C 14/042; C23C 14/243; C23C 14/54; H10K 71/166

(57) ABSTRACT

A mask assembly, an evaporation method, and an evaporation device. The mask assembly comprises: a plurality of rows of mask sheets (21) and x mask frames, wherein the plurality of rows of mask sheets (21) correspond to evaporation patterns; the plurality of rows of mask sheets (21) are divided into x groups; the mask sheets (21) in rows satisfying i+nx are sequentially arranged on an ith mask frame according to row numbers, so as to form an ith mask plate; first shielding portions (24) are arranged between mask sheets (21) in adjacent rows on the same mask frame; the distance between the edges of the mask sheets (21) in the adjacent rows on the same mask frame is less than the sum of widths of mask sheets (21) in other rows between the row numbers of the adjacent rows of mask sheets (21); i and x are both integers, i is less than or equal to x, x is greater than 1, and n is a non-negative integer. The mask assembly reduces the gap between effective evaporation areas of adjacent mask sheets (21), thereby improving the utilization rate of a target substrate (20).

The present disclosure is a national phase entry of International Application No. PCT/CN2023/110462, filed on Aug. 1, 2023, which claims the priority to Chinese Patent Disclosure No. 202211397946.7, titled “MASK ASSEMBLY, EVAPORATION METHOD, AND EVAPORATION DEVICE”, filed on Nov. 9, 2022 with the China National Intellectual Property Administration, which are both incorporated herein by reference in their entireties.

### FIELD

The present disclosure relates to the field of display and, in particular, to a mask assembly, an evaporation method, and an evaporation device.

### BACKGROUND

Compared with LCD displays, OLED displays have*—numerous advantages, for example, better low-temperature performance, faster response time, and richer colors for accurate display, and can be made thinner in thickness and lighter in weight. As a result, the OLED displays, with their superior performance, are gradually replacing the LCD displays that have already established a large market presence.

In the evaporation machine used for manufacturing OLED devices, a precision metal mask plate is required. The precision metal mask plate typically includes multiple mask sheets. Since the mask sheets are easily deformed under influence of environment such as temperature, a wide margin is generally provided for each of the mask sheets, resulting in a large spacing between effective evaporation areas of the adjacent mask sheets, and thus leading to a low utilization rate of substrate. Furthermore, this method is generally only suitable for the production of small-sized OLED devices.

### SUMMARY

The problem to be solved by the present disclosure is the large spacing between effective evaporation areas of the adjacent mask sheets and the low utilization rate of substrate caused by the wide margin necessarily provided for each of the mask sheets since they are easily deformed under influence of environment such as temperature in the conventional technology.

In order to solve or at least partially alleviate the above problem, there are provided a mask assembly, and an evaporation method and an evaporation device for use with the mask assembly.

A mask assembly is provided according to the present disclosure, including multiple rows of mask sheets and x mask frames. The multiple rows of mask sheets correspond to an evaporation pattern.

The multiple rows of mask sheets are divided into x groups.

The mask sheets of rows with row numbers of i+nx are sequentially arranged on an i^{th} mask frame according to the row numbers, so as to form an i^{th} mask plate.

A first shielding portion is arranged at either or any of rows of the mask sheets on a same mask frame.

A distance between edges of the mask sheets of every two adjacent rows on a same mask frame is less than sum of widths of the mask sheets of other rows with row numbers between the row numbers of the every two adjacent rows.

i and x are both positive integers, and i is less than or equal to x; x is greater than 1; and n is a non-negative integer.

In one embodiment, a gap is provided between each of the mask sheets and the first shielding portion adjacent to the mask sheet, and the gap is greater than or equal to sum of maximum expansion amounts of the mask sheet and the first shielding portion.

In one embodiment, a second shielding portion is disposed at each gap.

In one embodiment, the second shielding portion contains magnetic material.

In one embodiment, each of the mask sheets and the first shielding portion adjacent to one side of the mask sheet are integrally formed.

In one embodiment, the evaporation pattern includes a plurality of evaporation units arranged in an array, and each row of the mask sheet corresponds to a row of evaporation units in the evaporation pattern.

In one embodiment, the evaporation pattern includes a plurality of evaporation units arranged in an array. Except for the first and last rows of the mask sheets, each row of the mask sheet corresponds to a part of the preceding row of the evaporation units and a part of the succeeding row of the evaporation units in the evaporation pattern.

In one embodiment, the evaporation pattern includes a single evaporation unit.

In one embodiment, each mask sheet and each first shielding portion have the same thickness.

An evaporation method performed by using the mask assembly provided according to any one of the above embodiments. The method includes:
sequentially using the 1^{st} to x^{th} mask plates to perform evaporation on a target substrate.

In one embodiment, performing evaporation on the target substrate by using the i^{th} mask plate includes:
controlling relative movement between an evaporation source and the i^{th} mask plate in a movement direction parallel to a plane of the i^{th} mask plate and perpendicular to a length direction of the mask sheets.

In one embodiment, sequentially using the 1^{st} to x^{th} mask plates to perform evaporation on a target substrate includes:
controlling speed of the relative movement between the evaporation source and each mask plate to be smaller at a first position than at a second position. The first position refers to a position where the evaporation source is underneath the mask sheet, and the second position refers to a position where the evaporation source is not underneath the mask sheet.

An evaporation device is further provided according to an embodiment of the present disclosure, including an evaporation source and the mask assembly according to any one of the above embodiments. The mask assembly is disposed between the evaporation source and the target substrate.

In one embodiment, the evaporation device includes at least one evaporation chamber.

The evaporation chamber includes multiple evaporation zones, and the multiple mask plates of the mask assembly are respectively used in the multiple evaporation zones to perform evaporation on the target substrate.

In one embodiment, the multiple evaporation zones within the same evaporation chamber are communicated and share the same evaporation source. The evaporation source is used to scan and evaporate the plurality of evaporation zones successively.

In one embodiment, the evaporation device includes a mask plate storage chamber configured to store at least one mask assembly.

In one embodiment, the evaporation device includes multiple mask plate storage chambers. Different mask plate storage chambers store different mask assemblies, and the same mask plate storage chamber stores multiple mask plates of the same mask assembly.

In one embodiment, the evaporation device includes at least one evaporation group. Different evaporation groups correspond to different mask assemblies.

Each of the evaporation groups includes multiple evaporation chambers and multiple mask plate storage chambers. The mask plates of the same mask assembly are stored respectively in the multiple mask plate storage chambers in the same evaporation group. The evaporation is performed on the target substrate in the plurality of evaporation chambers in a same evaporation group by using the plurality of mask plates in their corresponding mask plate storage chambers of the same evaporation group.

### Beneficial effects

Compared with the conventional technology, the embodiments of the present disclosure has the following advantages.

A mask assembly provided according to the present disclosure includes multiple rows of mask sheets and x mask frames. The multiple rows of mask sheets correspond to an evaporation pattern. In the present disclosure, the multiple rows of mask sheets are divided into x groups, and the mask sheets of rows with row numbers of i+nx are sequentially arranged on an i^{th} mask frame according to the row numbers, so as to form an i^{th} mask plate. Additionally, a first shielding portion is arranged at either or any of rows of the mask sheets on a same mask frame. Since the distance between the edges of the mask sheets of the adjacent rows on the same mask frame is less than the sum of widths of the mask sheets of other rows with row numbers between the row numbers of the adjacent rows of mask sheets, after sequentially using the 1^{st} to the x^{th} mask plates to perform evaporation on a target substrate, the spacing between the effective evaporation areas of adjacent mask sheets can be reduced, to improve the utilization rate of the target substrate.

It is to be understood that both the foregoing general description and the following detailed description are exemplary and explanatory only and are not restrictive of the present disclosure.

### BRIEF DESCRIPTION OF THE DRAWINGS

In order to more clearly explain the embodiments of the present disclosure, the drawings used in the description of the embodiments are briefly described below.

FIG. 1 is a schematic structural view of a mask plate in the conventional technology;

FIG. 2 is a schematic structural view of a mask assembly provided according to an embodiment of the present disclosure;

FIG. 3 shows a evaporation pattern formed on a target substrate by evaporation using the mask assembly shown in FIG. 2;

FIG. 4 is a schematic structural view of another mask assembly provided according to an embodiment of the present disclosure;

FIG. 5 is a schematic structural view of still another mask assembly provided according to an embodiment of the present disclosure;

FIG. 6 is a schematic cross-sectional view taken along line C1C2 in FIG. 5;

FIG. 7 is a schematic view showing evaporation on a target substrate by using a mask plate of a mask assembly provided according to an embodiment of the present disclosure;

FIG. 8 is a schematic structural view of yet another mask assembly provided according to an embodiment of the present disclosure;

FIG. 9 is a schematic structural view of further another mask assembly provided according to an embodiment of the present disclosure;

FIG. 10 shows a evaporation pattern formed after evaporation is performed by using a 1^{st} mask plate of the mask assembly in FIG. 9;

FIG. 11 shows a evaporation pattern formed after evaporation is performed by using a 2^{nd} mask plate of the mask assembly in FIG. 9;

FIG. 12 is a schematic view showing a evaporation pattern formed after a first evaporation is performed by using the mask assembly in FIG. 2 provided according to an embodiment of the present disclosure;

FIG. 13 is a schematic view showing a evaporation pattern formed after a second evaporation is performed by using the mask assembly in FIG. 2 provided according to an embodiment of the present disclosure;

FIG. 14 is a schematic structural view of an evaporation device provided according to an embodiment of the present disclosure;

FIG. 15 is a schematic view showing a evaporation process in an evaporation chamber of the evaporation device provided according to an embodiment of the present disclosure;

FIG. 16 is a schematic structural view of another evaporation device provided according to an embodiment of the present disclosure;

FIG. 17 is a schematic structural view of still another evaporation device provided according to an embodiment of the present disclosure;

FIG. 18 is a schematic structural view of yet another evaporation device provided according to an embodiment of the present disclosure; and

FIG. 19 is a schematic diagram showing a evaporation process in an evaporation group of the evaporation device provided according to an embodiment of the present disclosure.

### DETAILED DESCRIPTION OF THE EMBODIMENTS

Hereinafter, in order to make the embodiments of the present disclosure clearer, the embodiments of the present disclosure will be described clearly and completely with reference to the drawings of the embodiments of the present disclosure. It is apparent that the described embodiments are only some rather than all of embodiments of the present disclosure.

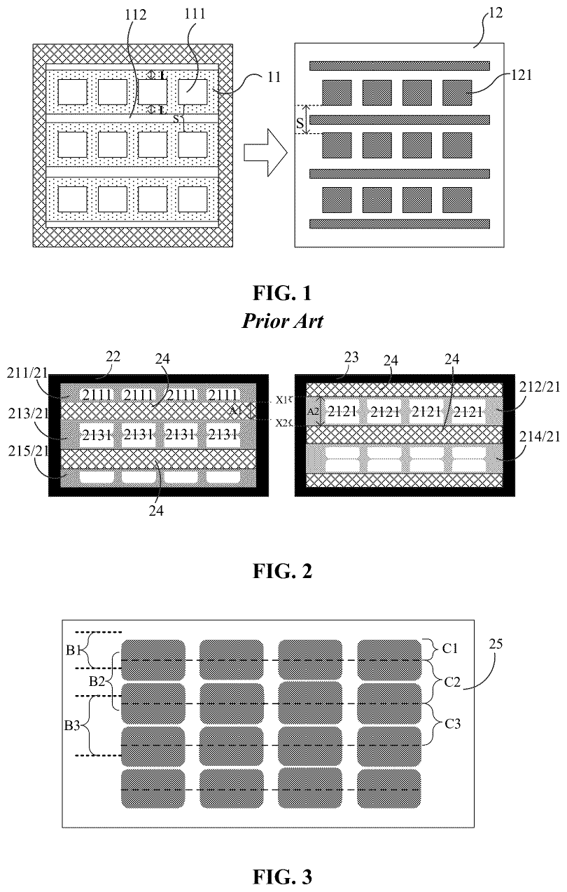

In a evaporation machine for manufacturing OLED devices, a precision metal mask plate is required. The precision metal mask plate typically includes multiple mask sheets, which are prone to deformation due to environmental factors such as temperature. Therefore, margin of the mask sheets are generally designed to be wide. This design, however, results in a larger spacing between effective evaporation areas of the adjacent mask sheets, leading to lower substrate utilization and limiting the production to small OLED devices. FIG. 1 is a schematic structural view of a mask plate in the conventional technology. The mask plate, as shown in FIG. 1, includes multiple mask sheets 11 that collectively serve to form a evaporation pattern (the evaporation pattern includes multiple rectangular patterns on the right side of FIG. 1). Due to the susceptibility of the mask sheets 11 to temperature and other environmental factors to cause deformation, the margins of the mask sheets 11 are made wide, i.e., the margins on both sides of the effective evaporation area 111 in the mask sheets 11 each have a large width L. In addition, a gap 112 inevitably exists between every two adjacent mask sheets 11 due to process reasons. The arrangement of the aforementioned mask plate results in a larger spacing S between the effective evaporation areas 111 of every two adjacent mask sheets, leading to a larger spacing S between every two adjacent rows of evaporation units 121 in the evaporation pattern formed on the substrate 12 using this mask plate.

Therefore, the utilization of the substrate is relatively low when using the mask plate in the conventional technology.

To address the aforementioned issues, a mask assembly, an evaporation method, and an evaporation device are provided according to the present disclosure, which can reduce the spacing between the effective evaporation areas of the adjacent mask sheets after sequentially using the 1^{st} to the x^{th} mask plates to perform evaporation on the target substrate, to improve the utilization of the target substrate. The method will be described with reference to specific embodiments below.

A mask assembly is provided according to an embodiment of the present disclosure, including multiple rows of mask sheets and x mask frames. The multiple rows of mask sheets correspond to an evaporation pattern to be formed on a target substrate. That is, when the multiple rows of mask sheets are arranged in sequence, the effective evaporation areas of the sequentially arranged mask sheets correspond to the evaporation pattern. In the embodiments of the present disclosure, the multiple rows of mask sheets are divided into x groups. The mask sheets of the rows with the row numbers of i+nx are sequentially arranged on an i^{th} mask frame according to row numbers, so as to form an i^{th} mask plate.

For example, the mask sheets of the 1^{st} row, the (1+x)^{th} row, the (1+2x)^{th} row, . . . , and the (1+nx)^{th} row are sequentially arranged on the 1^{st} mask frame according to row numbers, so as to form the 1^{st} mask plate; the mask sheets of the 2^{nd} row, the (2+x)^{th} row, the (2+2x)^{th} row, . . . , and the (2+nx)^{th} row are sequentially arranged on the 2^{nd} mask frame according to row numbers, so as to form the 2^{nd} mask plate; . . . ; and the mask sheets of the x^{th} row, the (x+x)^{th} row, the (x+2x)^{th} row, . . . , and the (x+nx)^{th} row are sequentially arranged on the x^{th} mask frame according to row numbers, so as to form the x^{th} mask plate.

Here, i and x are both positive integers, i being less than or equal to x; x is greater than 1; and n is a non-negative integer.

In the embodiments of the present disclosure, a first shielding portion is provided at either or any of the mask sheets of every two adjacent rows on a same mask frame. The first shielding portion is used to shield a gap between the mask sheets of adjacent rows when evaporation is performed by using the mask frame, so as to prevent the evaporation coating.

The distance between the edges of the mask sheets of adjacent rows on a same mask frame is less than a sum of the widths of mask sheets of other rows with the row numbers between the row numbers of the adjacent rows. In the embodiments of the present disclosure, x mask plates are provided. When performing evaporation on the target substrate, the 1^{st} to x^{th} mask plates are used sequentially to perform evaporation on the target substrate. Since the distance between the edges of the mask sheets of two adjacent rows on a same mask frame is less than the sum of the widths of mask sheets of other rows with the row numbers between the row numbers of the two adjacent rows, the mask sheets of rows with continuous row numbers on two mask plates used for successive evaporations may have overlapping areas.

For example, the mask sheet of the (1+2x)^{th} row on the 1^{st} mask plate overlaps with the mask sheet of the (2+2x)^{th} row on the 2^{nd} mask plate. Therefore, using the mask assembly of the present disclosure for evaporation can reduce the spacing between the effective evaporation areas of the mask sheets with continuous row numbers, improving the utilization rate of the target substrate.

An example where x is equal to 2 will be described below. FIG. 2 is a schematic structural view of a mask assembly provided according to an embodiment of the present disclosure. The mask assembly provided in this embodiment of the present disclosure includes multiple rows of mask sheets 21 (five rows exemplarily shown in FIG. 2) and two mask frames. The multiple rows of mask sheets 21 correspond to the evaporation pattern formed on the target substrate, that is, the mask sheets of the 1^{st} row to the 5^{th} row correspond to the evaporation pattern formed on the target substrate. In the left view of FIG. 2, from top to bottom, are mask sheet 211 of the 1^{st} row, mask sheet 213 of the 3^{rd} row, and mask sheet 215 of the 5^{th} row. In the right view of FIG. 2, from top to bottom, are mask sheet 212 of the 2^{nd} row and mask sheet 214 of the 4^{th} row.

In the embodiment of the present disclosure, the multiple rows of mask sheets 21 are divided into 2 groups. The mask sheets of the 1^{st} row, the 3^{rd} row and the 5^{th} row are arranged in sequence on the 1^{st} mask frame 22 to form the 1^{st} mask plate (the left mask plate as shown in FIG. 2). The mask sheets of the 2^{nd} row and the 4^{th} row are arranged in sequence on the 2^{nd} mask frame 23 to form the 2^{nd} mask plate (the right mask plate as shown in FIG. 2). That is, the mask sheets of the odd-numbered rows are arranged on the 1^{st} mask frame 22, and the mask sheets of the even-numbered rows are arranged on the 2^{nd} mask frame 23.

In the embodiment of the present disclosure, a first shielding portion 24 is further provided between adjacent rows of mask sheets on a same mask frame. Specifically, after the mask sheets are divided into two groups, the mask sheets of the first group (odd-numbered rows in FIG. 2) and the second group (even-numbered rows in FIG. 2) are located on different mask frames. Thus, there are no mask sheets placed on the 1^{st} mask plate in the positions where the mask sheets of the second group should be located, and there are no mask sheets placed on the 2nd mask plate in the positions where the mask sheets of the first group should be located. If the first shielding portion 24 is not provided at the positions where no mask sheet exists, coating may be formed at the positions during evaporation, affecting the correctness of the evaporation pattern. Therefore, it is necessary to provide the first shielding portion 24 to cover the part of the substrate at the positions where the mask sheets are not placed, preventing the unexpected coating of the areas other than the evaporation units during evaporation.

The distance between the edges of the mask sheets of adjacent rows on a same mask frame is less than the sum of the widths of mask sheets of other rows with the row numbers between the row numbers of the adjacent rows.

As an example, the 1^{st} to 3^{rd} rows of mask sheets as shown in FIG. 2 will be described. The distance between the lower edge of the mask sheet of the 1^{st} row and the upper edge of the mask sheet of the 3^{rd} row on the 1^{st} mask frame is A1. The mask sheet of the row with the row number between the row numbers of the 1^{st} and 3^{rd} rows of mask sheets on the 1^{st} mask frame is the mask sheet of the 2^{nd} row, which is located on the 2^{nd} mask frame. The width of the mask sheet of the 2^{nd} row is A2.

Due to the distance between the edges of mask sheets of adjacent rows on the same mask frame being less than the sum of the widths of mask sheets of other rows with the row numbers between the row numbers of the adjacent rows, the 1^{st} mask plate and the 2^{nd} mask plate are used sequentially for evaporation when using the mask assembly for evaporation. Therefore, the positions where the 1^{st} and 3^{rd} rows of mask sheets are located when evaporation is performed with the 1^{st} mask plate may partially overlap with the position where the 2^{nd} row of mask sheet is located when evaporation is performed with the 2^{nd} mask plate. As shown in FIG. 2, there may be an overlapping area X1 between the lower edge of the mask sheet of the 1^{st} row during evaporation performed with the 1^{st} mask plate and the upper edge of the mask sheet of 2^{nd} row during evaporation performed with the 2^{nd} mask plate, and there may be an overlapping area X2 between the upper edge of the mask sheet of 3^{rd} row during evaporation performed with the 1^{st} mask plate and the lower edge of the mask sheet of the 2^{nd} row during evaporation performed with the 2^{nd} mask plate. As a result, the lower edge of the pattern evaporated in the effective evaporation area 2111 of the mask sheet of the 1^{st} row may be in seamless connection with the upper edge of the pattern evaporated in the effective evaporation area 2121 of the mask sheet of the 2^{nd} row. Similarly, the lower edge of the pattern evaporated in the effective evaporation area 2121 of the mask sheet of the 2^{nd} row may be in seamless connection with the upper edge of the pattern evaporated in the effective evaporation area 2131 of the mask sheet of the 3^{rd} row, without being limited by the margin outside the effective evaporation areas of the mask sheets. FIG. 3 shows an evaporation pattern formed on a target substrate 25 by evaporation using the mask assembly shown in FIG. 2. As shown in FIG. 3, B1 represents the position corresponding to the mask sheet of 1^{st} row during evaporation performed with the 1^{st} mask plate; B3 represents the position corresponding to the mask sheet of 3^{rd} row during evaporation performed with the 1^{st} mask plate; B2 represents the position corresponding to the mask sheet of 2^{nd} row during evaporation performed with the 2^{nd} mask plate; C1 represents the position of the pattern evaporated in the effective evaporation area 2111 of the mask sheet of 1^{st} row during evaporation performed with the 1^{st} mask plate; C3 represents the position of the pattern evaporated in the effective evaporation area 2131 of the mask sheet of 3^{rd} row during evaporation performed with the 1^{st} mask plate; and C2 represents the position of the pattern evaporated in the effective evaporation area 2121 of the mask sheet of 2^{nd} row during evaporation performed with the 2^{nd} mask plate. As shown in FIG. 3, the distance between the lower edge of the pattern evaporated in the effective evaporation area of the mask sheet of 1^{st} row and the upper edge of the pattern evaporated in the effective evaporation area of the mask sheet of 2^{nd} row is reduced to 0. Similarly, the distance between the lower edge of the pattern evaporated in the effective evaporation area of the mask sheet of 2^{nd} row and the upper edge of the pattern evaporated in the effective evaporation area of the mask sheet of 3^{rd} row is reduced to 0, to improve the utilization rate of the target substrate. As can be known by comparing FIG. 3 with FIG. 1 (the right view of FIG. 1), for a target substrate of the same area, the utilization rate of the target substrate is higher when using the embodiments of the present disclosure.

It should be noted that the effective evaporation areas of the mask sheets of various rows in FIG. 2 may have precise evaporation patterns, and the specific form of these precise evaporation patterns is not limited herein.

In addition, in the embodiment of the present disclosure, the mask sheets are divided into groups, which can reduce the size of individual mask sheets, compared with the conventional technology in which various mask sheets are sequentially arranged on a single mask frame. As a result, the absolute expansion of the individual mask sheet due to environmental factors such as temperature becomes smaller, making it easier to align the mask plate with the target substrate and improving the alignment success rate. For example, when the aforementioned mask assembly is used to produce an OLED display panel by evaporation, multiple evaporation units arranged in an array as shown in FIG. 3 are formed (FIG. 3 shows sixteen evaporation units in a 4×4 array). Each evaporation unit corresponds to an OLED display panel area. The large panel shown in FIG. 3 is subsequently cut to form individual OLED display panels. Due to the reduced size of individual mask sheets, the absolute expansion of the individual mask sheet due to environmental factors such as temperature becomes smaller, which allows reduction in the size of the evaporation pattern of unit pixel of the OLED display panel in the effective evaporation area of the mask sheet, to also improve the resolution of the produced OLED display panel.

It should be noted that the multiple rows of mask sheets may be divided into three groups, four groups, or more groups, which is not limited herein. The principle of improving the utilization rate of the target substrate by dividing the multiple rows of mask sheets into three groups, four groups, or more groups is similar to the principle by dividing the multiple rows of mask sheets into two groups described above and will not be repeated here.

In some embodiments, there is a gap between the mask sheet and the adjacent first shielding portion. The gap is greater than or equal to the sum of the maximum expansion amounts of the mask sheet and the first shielding portion.

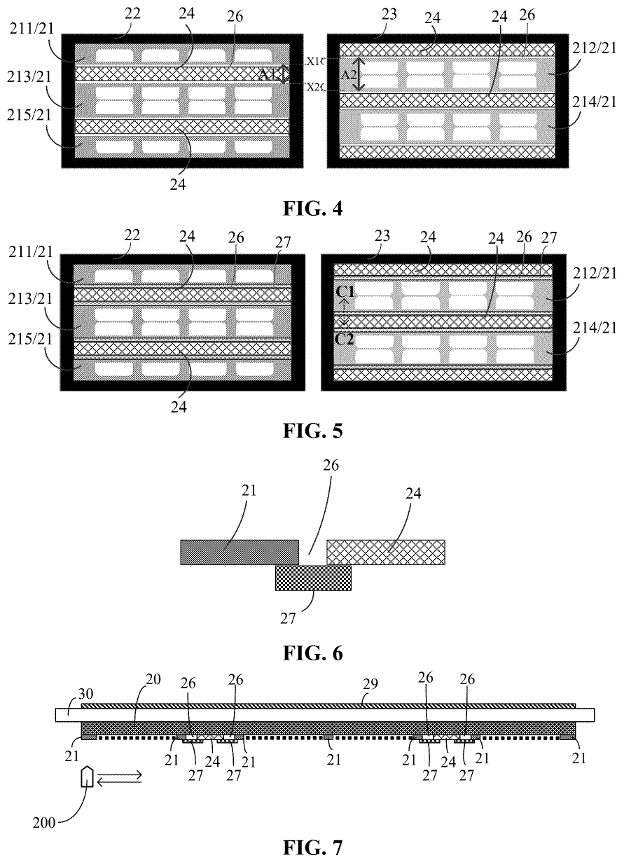

For instance, FIG. 4 is a schematic structural view of another mask assembly provided according to an embodiment of the present disclosure. As shown in FIG. 4, there is a gap 26 between the mask sheet 21 and the adjacent first shielding portion 24. The mask sheet and the first shielding portion may expand due to environmental factors such as temperature. If they come into contact and press against each other, wrinkles may occur on the mask sheet and the first shielding portion, affecting the accuracy of the evaporation pattern. Therefore, in the embodiment of the present disclosure, a gap is provided between the mask sheet and the adjacent first shielding portion, and the gap is greater than or equal to the sum of the maximum expansion amounts of the mask sheet and the first shielding portion, so as to prevent the mask sheet and the first shielding portion from pressing against each other when they expand.

In one embodiment, the width of the gap 26 is constant along the extension direction of the mask sheet.

In some embodiments, a second shielding portion 27 is disposed at the gap. FIG. 5 is a schematic structural view of another mask assembly provided according to an embodiment of the present disclosure. FIG. 6 is a schematic cross-sectional view taken along line C1C2 in FIG. 5. Specifically, as shown in FIGS. 5 and 6, a gap is provided between the mask sheet and the first shielding portion. Coating may be formed in the gap when evaporation is performed, affecting the evaporation pattern. Therefore, in the embodiment of the present disclosure, a second shielding portion 27 is provided at the gap to shield the gap. As shown in FIG. 6, the second shielding portion 27 is disposed on the gap 26 between the mask sheet 21 and the first shielding portion 24. The second shielding portion 27 is specifically used to prevent unexpected coating at the gap other than the evaporation pattern during evaporation.

In some embodiments, the second shielding portion contains a magnetic material.

For instance, FIG. 7 is a schematic view showing evaporation performed on a target substrate by using a 1^{st} mask plate according to an embodiment of the present disclosure. As shown in FIG. 7 (the mask frame is not shown), when evaporation is performed on the target substrate 20, a magnetic plate 29 is generally disposed on the back of the target substrate 20. In the embodiment of the present disclosure, the second shielding portion 27 is provided and contains a magnetic material. When evaporation is performed, the mask plate is placed on the target substrate 20. Since the second shielding portion 27 contains a magnetic material and the back of the target substrate 20 is provided with the magnetic plate 29, the magnetic plate on the back of the target substrate and the second shielding portion attract each other, stably attaching the mask sheet and the first shielding portion of the mask plate to the target substrate.

For instance, referring to FIG. 7, a pressing plate 30 may further be disposed between the target substrate 20 and the magnetic plate 29. The provision of the pressing plate can prevent misalignment between the target substrate and the mask sheet when the magnetic plate 29 is attached.

It should be noted that FIG. 7 only shows, some embodiments of the structure, and the dimensions, thicknesses, and sizes of various parts can be adjusted based on actual requirements, and are not limited herein.

In some embodiments, the mask sheet and the first shielding portion adjacent to a certain side are integrally formed.

As an example, the mask sheet and the first shielding portion adjacent to a side of the mask sheet may be integrally formed. When the mask sheet and the first shielding portion adjacent to its side are integrally formed, there is no gap between the mask sheet and the first shielding portion adjacent to that side. This prevents the mask sheet and the first shielding portion adjacent to its side from coming into contact and pressing against each other when they expand due to environmental factors such as temperature to cause wrinkles on the mask sheet and the first shielding portion, and also prevents coating from being formed during evaporation at the gap, which is provided therebetween, other than the evaporation units.

In some embodiments, the evaporation pattern includes multiple evaporation units arranged in an array. Each row of mask sheet corresponds to one row of evaporation units of the evaporation pattern.

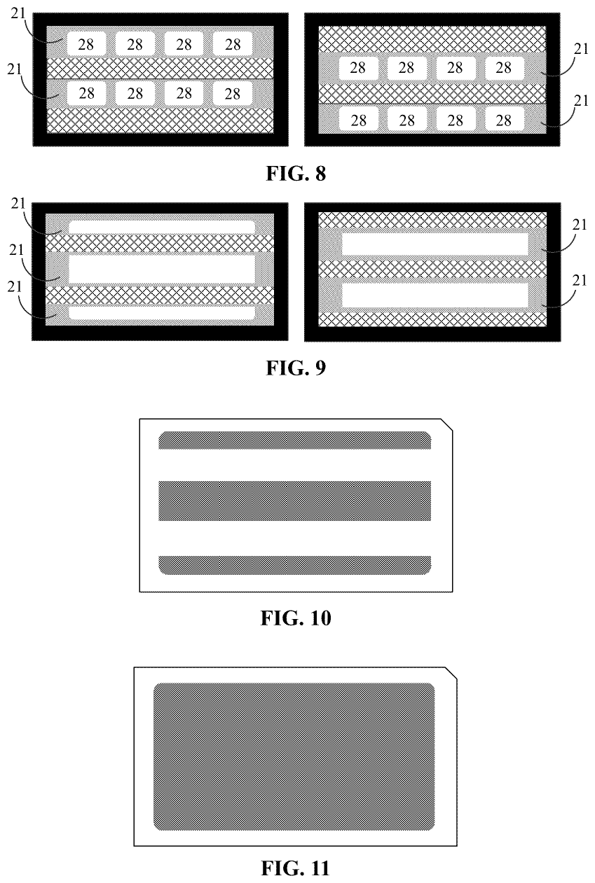

FIG. 8 is a schematic structural view of another mask assembly provided according to an embodiment of the present disclosure. As shown in FIG. 8, each row of mask sheet 21 corresponds to a row of evaporation units 28 in the evaporation pattern. That is, the effective evaporation area of each row of mask sheet corresponds to a row of evaporation units in the evaporation pattern.

When performing evaporation on a target substrate, the 1^{st} to x^{th} mask plates are sequentially used to perform evaporation on the target substrate. Since the distance between the edges of mask sheets of adjacent rows on a same mask frame is less than the sum of the widths of the mask sheets of the other rows with the row numbers between the row numbers of the adjacent rows, the mask sheets with adjacent row numbers of the mask plates used for adjacent evaporations may have overlapping areas. This arrangement can reduce the spacing between the effective evaporation areas of mask sheets with adjacent row numbers, to improve the utilization rate of the target substrate.

In some embodiments, the evaporation pattern includes multiple evaporation units arranged in an array. Except for the first and last rows of mask sheets, each row of mask sheet corresponds to a part of each of the evaporation units of the preceding row and a part of each of the evaporation units of the succeeding row in the evaporation pattern.

As an example, as shown in FIG. 2, the 1^{st} row of mask sheet on the left mask plate is the first row of mask sheet, and the 5^{th} row of mask sheet is the last row of mask sheet. The 1^{st} row of mask sheet corresponds only to a part of a row of evaporation units in the evaporation pattern, and the 5^{th} row of mask sheet corresponds only to a part of a row of evaporation units in the evaporation pattern. The 3^{rd} row of mask sheet on the left mask plate in FIG. 2, as well as the 2^{nd} and 4^{th} rows of mask sheets on the right mask plate, each corresponds to a part of the preceding row of the evaporation units and a part of the succeeding row of the evaporation units in the evaporation pattern. Therefore, except for the first and last rows of mask sheets, each row of mask sheet corresponds to a part of the preceding row of the evaporation units and a part of the succeeding row of the evaporation units in the evaporation pattern. With this arrangement, the distance between the edges of the evaporations performed by the mask sheets with adjacent row numbers may be zero, further improving the utilization rate of the target substrate.

In some embodiments, the evaporation pattern is a single evaporation unit.

As an example, FIG. 9 is a schematic structural view of another mask assembly provided according to an embodiment of the present disclosure; FIG. 10 shows a evaporation pattern formed after evaporation is performed by using the 1^{st} mask plate of the mask assembly in FIG. 9; and FIG. 11 shows a evaporation pattern formed after evaporation is carried out by using a 2^{nd} mask plate of the mask assembly in FIG. 9. The left diagram in FIG. 9 illustrates the structure of the 1^{st} mask plate, and the right diagram in FIG. 9 illustrates the structure of the 2^{nd} mask plate. After evaporation is performed by sequentially using the 1^{st} and 2^{nd} mask plates of the mask assembly shown in FIG. 9, a complete evaporation unit can be formed. Therefore, the mask assembly provided in the embodiments of the present disclosure may be used for evaporation to produce large-size devices, e.g., large-size OLED display panels.

In some embodiments, the thickness of the mask sheets is the same as the thickness of the first shielding portion.

As an example, the mask sheets and the first shielding portion are mounted on the same mask frame. During evaporation, the mask plate will be in contact with the target substrate. If the thickness of the mask sheets is different from the thickness of the first shielding portion, it may affect the flatness of the contact between the mask plate and the target substrate, to affect the evaporation pattern on the target substrate.

An evaporation method carried out by using a mask assembly is further provided according to an embodiment of the present disclosure. The method may adopt the mask assembly described in any one of the above embodiments, and the method includes:
performing evaporation on a target substrate by sequentially using the 1^{st} to the x^{th} mask plates.

Exemplarily, an example where x equals to 2 will be described below. As shown in FIG. 2, the evaporation is performed on the target substrate by sequentially using the left-side mask plate in FIG. 2 (referred to as the 1^{st} mask plate) and the right-side mask plate in FIG. 2 (referred to as the 2^{nd} mask plate). Since the patterns of the 1^{st} and 2^{nd} mask plates are complementary, the target evaporation pattern may be formed by sequential evaporations.

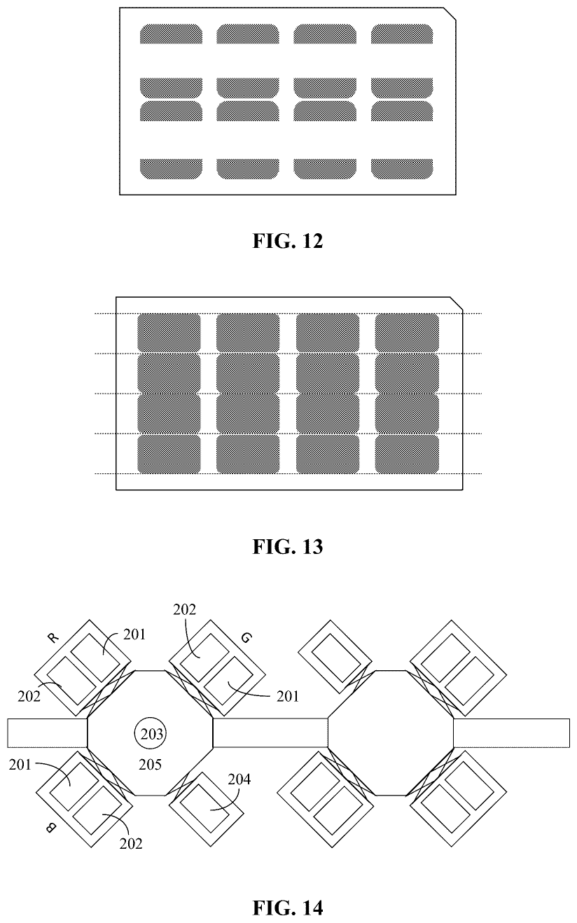

In one embodiment, FIG. 12 is a schematic view showing a evaporation pattern formed after a first evaporation is performed by using the mask assembly in FIG. 2 provided according to an embodiment of the present disclosure, and FIG. 13 is a schematic view showing a evaporation pattern formed after a second evaporation is performed by using the mask assembly in FIG. 2 provided according to an embodiment of the present disclosure. An example of the 1^{st} to 3^{rd} rows of mask sheets will be described. The positions where the 1^{st} and 3^{rd} rows of mask sheets are located when evaporation is performed by using the 1^{st} mask plate may partially overlap with the position where the 2^{nd} row of mask sheet is located when evaporation is performed with the 2^{nd} mask plate. As shown in FIG. 2, there may be an overlapping area X1 between the lower edge of the 1^{st} row of mask sheet during evaporation performed with the 1^{st} mask plate and the upper edge of the 2^{nd} row of mask sheet during evaporation performed with the 2^{nd} mask plate. Similarly, there may be an overlapping area X2 between the upper edge of the 3^{rd} row of mask sheet during evaporation performed with the 1^{st} mask plate and the lower edge of the 2^{nd} row of mask sheet during evaporation performed with the 2^{nd} mask plate. Therefore, the distance between the lower edge of the pattern evaporated in the effective evaporation area 2111 of the 1^{st} row of mask sheet and the upper edge of the pattern evaporated in the effective evaporation area 2121 of the 2^{nd} row of mask sheet is significantly reduced, for example, achieving seamless joining. Likewise, the distance between the lower edge of the pattern evaporated in the effective evaporation area 2121 of the 2^{nd} row of mask sheet and the upper edge of the pattern evaporated in the effective evaporation area 2131 of the 3^{rd} row of mask sheet is significantly reduced, for example, achieving seamless joining, without being restricted by the width of margin outside the effective evaporation areas of the mask sheets. As shown in FIG. 13, the distance between the lower edge of the pattern evaporated in the effective evaporation area of the 1^{st} row of mask sheet and the upper edge of the pattern evaporated in the effective evaporation area of the 2^{nd} row of mask sheet is reduced to zero. Similarly, the distance between the lower edge of the pattern evaporated in the effective evaporation area of the 2^{nd} row of mask sheet and the upper edge of the pattern evaporated in the effective evaporation area of the 3^{rd} row of mask sheet is reduced to zero, to improve the utilization rate of the target substrate.

Reference may be made to FIGS. 1 and 13. As shown in FIG. 1, the right view illustrates a evaporation pattern in the conventional technology. In addition to the desired evaporation pattern, there are coatings evaporated due to the presence of gaps 112. Therefore, when cutting the evaporation pattern, two cuts are required in the horizontal direction to separate the evaporation units of different rows. As shown in FIG. 13, for the evaporation pattern formed after two evaporations in this embodiment, only a single cut is needed in the horizontal direction since there is no or only a very small gap between the evaporation units on the mask sheets. With the above design, the number of cuts required during the separation process is reduced, to improve production efficiency.

In some embodiments, when evaporation is performed on the target substrate by using the i^{th} mask plate, the method includes:
controlling relative movement between the evaporation source and the i^{th} mask plate in the movement direction parallel to the plane of the i^{th} mask plate and perpendicular to the length direction of the mask sheet.

As an example, as shown in FIG. 7, controlling the relative movement between the evaporation source 200 and the 1^{st} mask plate may include fixing the 1^{st} mask plate and moving the evaporation source 200 in a direction parallel to the plane of the 1^{st} mask plate and perpendicular to the length direction of the mask sheet 21. In one embodiment, controlling the relative movement between the evaporation source 200 and the 1^{st} mask plate may include fixing the evaporation source 200 and moving the 1^{st} mask plate in a direction parallel to the plane of the 1^{st} mask plate and perpendicular to the length direction of the mask sheet 21.

In some embodiments, when evaporation is performed on the target substrate by sequentially using the 1^{st} to the x^{th} mask plates, the method further includes:
controlling speed of the relative movement between the evaporation source and the mask plate to be smaller at a first position than at a second position.

The first position refers to the position where the evaporation source is underneath the mask sheet, and the second position refers to the position where the evaporation source is not underneath the mask sheet.

Specifically, during the evaporation process, evaporation is only required to be performed in the evaporation units on the mask sheets, and there is no need to perform the evaporation at the position where no mask sheet of the mask assembly is provided (for example, where a first shielding portion is located). However, it is difficult to prevent evaporation from occurring when the evaporation source passes by the first shielding portion. Therefore, it is desired to move the evaporation source at an increased speed when passing over unexpected evaporation areas, and at a normal speed when passing over the mask sheets for evaporation.

Based on this, the position where the evaporation source is under the mask sheet is referred to as the first position, and the position where the evaporation source is not under the mask sheet is referred to as the second position. The relative movement speed between the evaporation source and the mask plate shall be smaller at the first position than at the second position. In this way, it is possible to avoid waste of evaporation material at the second position. And, since the relative movement speed increases at the second position, the overall movement time is reduced, to save evaporation time and materials.

An evaporation device is further provided according to an embodiment of the present disclosure, which includes an evaporation source and the mask assembly described in any one of the above embodiments. The mask assembly is positioned between the evaporation source and the target substrate.

In some embodiments, the evaporation device includes at least one evaporation chamber. Each evaporation chamber includes multiple evaporation zones. Each of the multiple evaporation zones is equipped with a corresponding mask plate of the mask assembly to perform evaporation on the target substrate.

FIG. 14 is a schematic structural view of an evaporation device provided according to an embodiment of the present disclosure. As an example, the evaporation device including three evaporation chambers will be described. As shown in FIG. 14, the three evaporation chambers are evaporation chamber R, evaporation chamber G, and evaporation chamber B. Different evaporation chambers use the respective mask assemblies for evaporation. For evaporation of OLED display panel, the evaporation device provided in this embodiment of the present disclosure may be used to evaporate and form the light-emitting layer pattern corresponding to the red pixels in the evaporation chamber R, to evaporate and form the light-emitting layer pattern corresponding to the green pixels in the evaporation chamber G, and to evaporate and form the light-emitting layer pattern corresponding to the blue pixels in the evaporation chamber B.

As an example, each evaporation chamber may include two evaporation zones: a first evaporation zone 201 and a second evaporation zone 202. In each of the evaporation chambers, evaporation is sequentially performed in the first evaporation zone 201 and the second evaporation zone 202. Evaporation is performed in the first evaporation zone 201 in the evaporation chamber R by using a 1^{st} mask plate of a mask assembly corresponding to the evaporation chamber R, and in the second evaporation zone 202 in the evaporation chamber R by using a 2^{nd} mask plate of the mask assembly corresponding to the evaporation chamber R. Similarly, evaporation is performed in the first evaporation zone 201 in the evaporation chamber G by using a 1^{st} mask plate of a mask assembly corresponding to the evaporation chamber G, and in the second evaporation zone 202 in the evaporation chamber G by using a 2^{nd} mask plate of the mask assembly corresponding to the evaporation chamber G. Similarly, evaporation is performed in the first evaporation zone 201 in the evaporation chamber B by using a 1^{st} mask plate of a mask assembly corresponding to the evaporation chamber B, and in the second evaporation zone 202 in the evaporation chamber B by using a 2^{nd} mask plate of the mask assembly corresponding to the evaporation chamber B. In the embodiment of the present disclosure, by providing each evaporation chamber with multiple evaporation zones in which the multiple mask plates of the mask assembly are respectively used to perform the evaporation on the target substrate, the number of evaporation chambers and equipment costs may be reduced.

In some embodiments, the evaporation zones of a same evaporation chamber may be communicated with each other and share a same evaporation source. The evaporation zones are sequentially scanned and evaporated by the evaporation source.

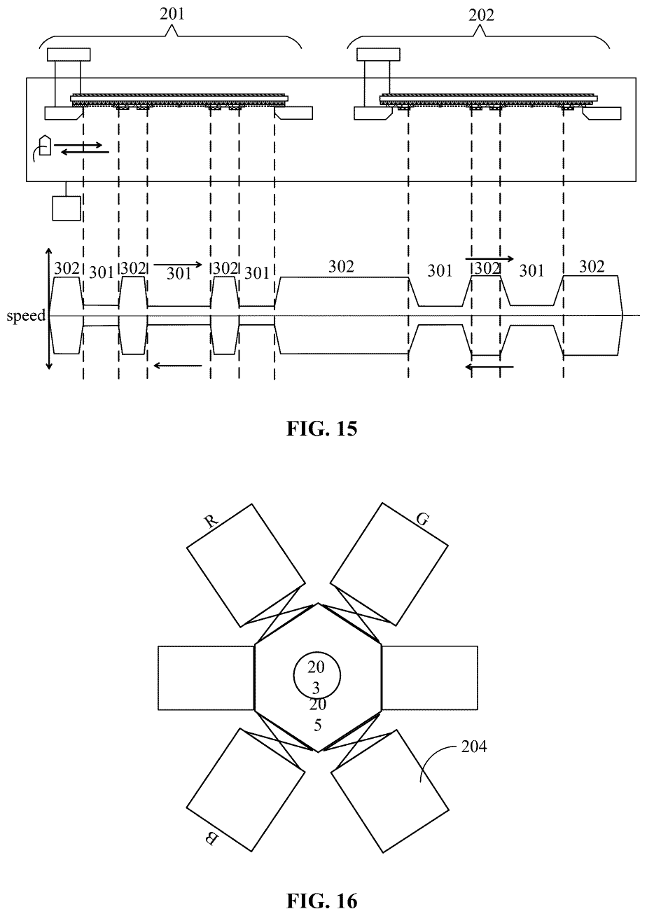

Referring to FIG. 15, an evaporation chamber including two evaporation zones, such as the first evaporation zone 201 and the second evaporation zone 202 shown in FIG. 15, is taken as an example. These two evaporation zones (the first evaporation zone 201 and the second evaporation zone 202) within a same evaporation chamber are communicated and share a common evaporation source 200. In the evaporation chamber, the evaporation source 200 sequentially performs scanning and evaporation in the first evaporation zone 201 and the second evaporation zone 202. This helps reduce difference between coatings formed during the two evaporations and also reduce the number of evaporation sources and vacuum components, to save costs.

It should be noted that FIG. 15 only illustrates an example with one evaporation chamber of an evaporation device including two evaporation zones. The evaporation device may include multiple evaporation chambers, and the number of evaporation zones in different evaporation chambers may be the same or different. The number of evaporation zones in the evaporation chamber is not limited herein.

In one embodiment, as also shown in FIG. 15, during the scanning and evaporation process of the evaporation source 200 performed sequentially in the evaporation zone 201 and the evaporation zone 202 within the same evaporation chamber, the speed of relative movement between the evaporation source 200 and the mask plate may be controlled to be smaller at the first position 301 than at the second position 302. The first position 301 refers to the position where the evaporation source is under the mask plate, and the second position 302 refers to the position where the evaporation source is not under the mask plate.

In some embodiments, the evaporation device may further include a mask plate storage chamber for storing at least one mask assembly.

As an example, during the evaporation process, the required evaporation patterns in different evaporation chambers may be different. Therefore, different mask assemblies may be used for evaporation in different evaporation chambers. For example, in the manufacturing process of an OLED display panel, the first mask assembly may be used in the evaporation chamber R to form the light-emitting layer pattern corresponding to red pixels. The first mask assembly includes x1 mask plates. The second mask assembly may be used in the evaporation chamber G to form the light-emitting layer pattern corresponding to green pixels. The second mask assembly includes x2 mask plates. The third mask assembly may be used in the evaporation chamber B to form the light-emitting layer pattern corresponding to blue pixels. The third mask includes x3 mask plates. The values of x1, x2, and x3 may be equal or different. As shown in FIG. 16, the evaporation device includes a mask plate storage chamber 204, which is used to store the x1 mask plates required by the evaporation chamber R, the x2 mask plates required by the evaporation chamber G, and the x3 mask plates required by the evaporation chamber B. In use, a mechanical arm 203 transfers the individual mask plates from the mask plate storage chamber 204 to the corresponding evaporation chambers for coating.

In some embodiments, the evaporation device includes multiple mask plate storage chambers for storing different mask assemblies. Each mask plate storage chamber holds multiple mask plates of a same mask assembly.

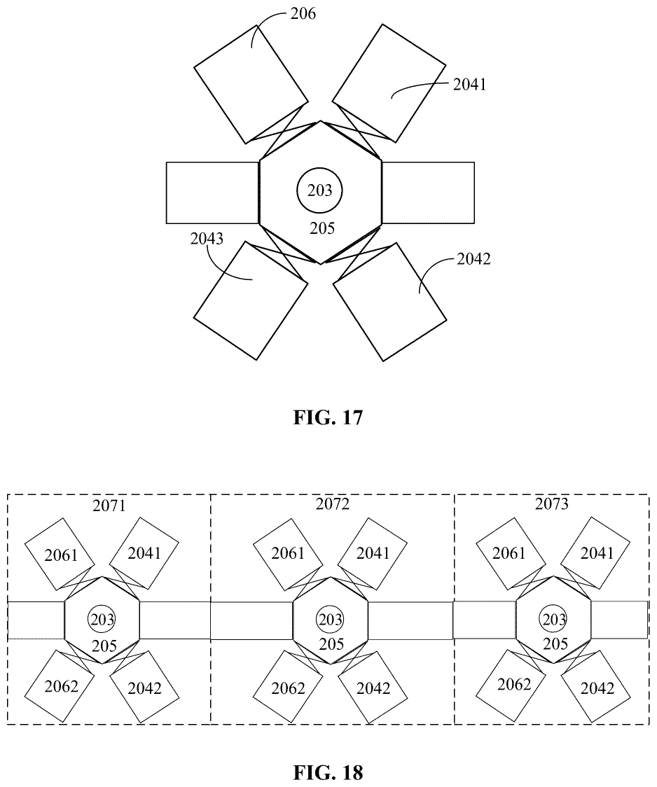

As an example, FIG. 17 is a schematic structural view of another evaporation device provided according to an embodiment of the present disclosure. As shown in FIG. 17, the evaporation device includes three mask plate storage chambers: mask plate storage chamber 2041, mask plate storage chamber 2042, and mask plate storage chamber 2043. The mask plate storage chamber 2041 stores the mask assembly used for red pixel evaporation. The mask plate storage chamber 2042 stores the mask assembly used for green pixel evaporation. The mask plate storage chamber 2043 stores the mask assembly used for blue pixel evaporation. When the mask plates are needed for evaporation, the mechanical arm 203 in a transfer chamber 205 sequentially transfers the mask plates from the mask plate storage chambers into the evaporation chamber 206 for coating. Since different mask assemblies correspond to different evaporation patterns, the number of the mask plates in each mask assembly may be determined as actually needed.

In some embodiments, the evaporation device includes at least one evaporation group. The different evaporation groups correspond to different mask assemblies.

Each of the evaporation groups includes multiple evaporation chambers and multiple mask plate storage chambers. The multiple mask plates of a same mask assembly are stored respectively in the multiple mask plate storage chambers in a same evaporation group. The evaporation is performed on a target substrate in the multiple evaporation chambers in a same evaporation group by using the multiple mask plates in their corresponding mask plate storage chambers in the same evaporation group.

As an example, FIG. 18 is a schematic structural view of another evaporation device provided according to an embodiment of the present disclosure. As shown in FIG. 18, the evaporation device includes three evaporation groups, namely, evaporation group 2071, evaporation group 2072, and evaporation group 2073. The evaporation group 2071 is used for evaporation to form a light-emitting layer pattern corresponding to red pixels; the evaporation group 2072 is used for evaporation to form a light-emitting layer pattern corresponding to green pixels; and the evaporation group 2073 is used for evaporation to form a light-emitting layer pattern corresponding to blue pixels.

Based on this, the evaporation group 2071 is taken as an example for description.

The evaporation group 2071 includes evaporation chambers 2061 and 2062, and mask plate storage chambers 2041 and 2042. The evaporation chamber 2061 may use the 1^{st} mask plate stored in the mask plate storage chamber 2041 during evaporation, and the evaporation chamber 2062 may use the 2^{nd} mask plate stored in the mask plate storage chamber 2042 during evaporation. When a mask plate is needed for evaporation, the mechanical arm 203 in the transfer chamber 205 transfers the 1^{st} mask plate from the mask plate storage chamber 2041 into the evaporation chamber 2061 for coating, and transfers the 2^{nd} mask plate from the mask plate storage chamber 2042 into the evaporation chamber 2062 for coating. After completing the evaporation work in the evaporation group 2071, the substrate is sent to the evaporation group 2072 for the next evaporation; and after completing the evaporation work in the evaporation group 2072, the substrate is sent to the evaporation group 2073 for the next evaporation. Since each evaporation group is only responsible for evaporating the light-emitting layer of one color pixel, contamination of the evaporation materials of light-emitting layers of different color pixels during the evaporation process can be avoided.

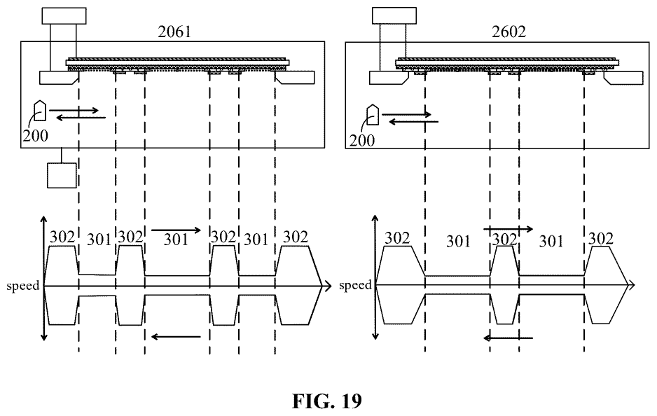

FIG. 19 is a schematic diagram showing an evaporation process in an evaporation group of the evaporation device provided according to an embodiment of the present disclosure. Referring to FIG. 19 and taking the evaporation in evaporation group 2071 in FIG. 18 as an example, the evaporation chamber 2061 uses the 1^{st} mask plate stored in the mask plate storage chamber 2041 during evaporation. During evaporation in the evaporation chamber 2061, the speed of relative movement between the evaporation source 200 and the 1^{st} mask plate is controlled to be smaller at the first position 301 than at the second position 302. Here, the first position 301 refers to the position where the evaporation source is under the mask plate, and the second position 302 refers to the position where the evaporation source is not under the mask plate. The evaporation chamber 2062 uses the 2^{nd} mask plate stored in the mask plate storage chamber 2042 during evaporation. During evaporation in the evaporation chamber 2062, the speed of relative movement between the evaporation source 200 and the 2^{nd} mask plate is also controlled to be smaller at the first position 301 than at the second position 302. Here, the first position 301 refers to the position where the evaporation source is under the mask plate, and the second position 302 refers to the position where the evaporation source is not under the mask plate.

It should be noted that in the present disclosure, relational terms such as “first” and “second” are only used to distinguish one entity or operation from another entity or operation, but do not indicate or imply an actual relationship or order of these entities or operations. Furthermore, the term “comprise”, “include” or any other variation thereof is intended to cover a non-exclusive inclusion, so that a process, a method, an article, or a device including a set of elements includes not only those elements, but also other elements not expressly listed or elements inherent in such a process, method, article, or device. Unless expressively limited, the statement “including a . . . ” does not exclude the case that other similar elements may exist in the process, method, article or device including the series of elements.

The above are only specific implementations of the present disclosure, such that those skilled in the art can understand or implement the present disclosure. It is apparent for those skilled in the art to make many modifications to these embodiments. The general principle defined herein may be applied to other embodiments without departing from spirit or scope of the present disclosure. Therefore, the present disclosure is not limited to these embodiments illustrated in the present disclosure, but needs to conform to the broadest scope consistent with the principles and novel features disclosed in the present disclosure.

### INDUSTRIAL APPLICABILITY

The mask assembly disclosed in the present disclosure has the advantage that, since the distance between the edges of the mask sheets in the adjacent rows on the same mask frame is less than the sum of the widths of the mask sheets in the other rows between the row numbers of these adjacent rows, after sequentially using the 1^{st} to the x^{th} mask plates to perform evaporation on a target substrate, the gap between the effective evaporation areas of adjacent mask sheets can be reduced, to improve the utilization rate of the target substrate.

Therefore, it exhibits significant disclosure value in the evaporation fabrication process of display screens and possesses strong industrial practicality.

1. A mask assembly, comprising a plurality of rows of mask sheets and x mask frames, wherein
the plurality of rows of mask sheets correspond to an evaporation pattern;
the plurality of rows of mask sheets are divided into x groups;
the mask sheets of rows with row numbers of i+nx are sequentially arranged on an i^{th} mask frame according to the row numbers, so as to form an i^{th} mask plate;
a first shielding portion is arranged at either or any of rows of the mask sheets on a same mask frame;
a distance between edges of the mask sheets of every two adjacent rows on a same mask frame is less than sum of widths of the mask sheets of other rows with row numbers between the row numbers of the every two adjacent rows; and
where i and x are both positive integers, i is less than or equal to x, x is greater than 1, and n is a non-negative integer.

2. The mask assembly according to claim 1, wherein a gap is provided between each of the mask sheets and the first shielding portion adjacent to the mask sheet, and the gap is greater than or equal to sum of maximum expansion amounts of the mask sheet and the first shielding portion.

3. The mask assembly according to claim 2, wherein a second shielding portion is disposed at each gap.

4. The mask assembly according to claim 3, wherein the second shielding portion contains magnetic material.

5. The mask assembly according to claim 1, wherein each of the mask sheets and the first shielding portion adjacent to one side of the mask sheet are integrally formed.

6. The mask assembly according to claim 1, wherein the evaporation pattern comprises a plurality of evaporation units arranged in an array, and each row of the mask sheet corresponds to a row of evaporation units in the evaporation pattern.

7. The mask assembly according to claim 1, wherein the evaporation pattern comprises a plurality of evaporation units arranged in an array, and except for the first and last rows of the mask sheets, each row of the mask sheet corresponds to a part of a row of the evaporation units and a part of the succeeding row of the evaporation units in the evaporation pattern.

8. The mask assembly according to claim 1, wherein the evaporation pattern comprises a single evaporation unit.

9. The mask assembly according to claim 1, wherein each mask sheet and each first shielding portion have the same thickness.

10. An evaporation method performed by using the mask assembly according to claim 1, wherein the method comprises:
sequentially using the 1^{st} to x^{th} mask plates to perform evaporation on a target substrate.

11. The evaporation method according to claim 10, wherein performing evaporation on the target substrate by using the i^{th} mask plate comprises:
controlling relative movement between an evaporation source and the i^{th} mask plate in a movement direction parallel to a plane of the i^{th} mask plate and perpendicular to a length direction of the mask sheets.

12. The evaporation method according to claim 11, wherein sequentially using the 1^{st} to x^{th} mask plates to perform evaporation on a target substrate comprises:
controlling speed of the relative movement between the evaporation source and each mask plate to be smaller at a first position than at a second position;
wherein the first position refers to a position where the evaporation source is underneath each mask sheet, and the second position refers to a position where the evaporation source is not underneath each mask sheet.

13. An evaporation device, comprising an evaporation source and the mask assembly according to claim 1,
wherein the mask assembly is disposed between the evaporation source and a target substrate.

14. The evaporation device according to claim 13, comprising at least one evaporation chamber, wherein
each of the at least one evaporation chamber comprises a plurality of evaporation zones, and a plurality of mask plates of the mask assembly are respectively used in the plurality of evaporation zones to perform evaporation on the target substrate.

15. The evaporation device according to claim 14, wherein the plurality of evaporation zones within a same evaporation chamber are communicated and share a same evaporation source, and the evaporation source is used to scan and evaporate over the plurality of evaporation zones successively.

16. The evaporation device according to claim 13, comprising a mask plate storage chamber, which is configured to store at least one mask assembly.

17. The evaporation device according to claim 13, comprising a plurality of mask plate storage chambers, wherein different mask plate storage chambers store different mask assemblies, and a same mask plate storage chamber stores the plurality of mask plates of a same mask assembly.

18. The evaporation device according to claim 13, comprising at least one evaporation group, wherein different evaporation groups correspond to different mask assemblies;
each of the evaporation groups comprises a plurality of evaporation chambers and a plurality of mask plate storage chambers;
the plurality of mask plates of a same mask assembly are stored respectively in the plurality of mask plate storage chambers in a same evaporation group; and
evaporation is performed on the target substrate in the plurality of evaporation chambers in a same evaporation group by using the plurality of mask plates in their corresponding mask plate storage chambers of the same evaporation group.
